(19) United States
(12) Patent Application Publication
(10) Pub. No.: US 2016/0202954 A1
(43) Pub. Date: Jul. 14, 2016

(54) VOLTAGE CONTROLLED NANO-MAGNETIC RANDOM NUMBER GENERATOR

(71) Applicant: INTEL CORPORATION, Santa Clara, CA (US)

(72) Inventors: SASIKANTH MANIPATRUNI, Hillsboro, OR (US); DMITRI NIKONOV, Beaverton, OR (US); IAN YOUNG, Portland, OR (US)

(21) Appl. No.: 14/912,895

(22) PCT Filed: Sep. 27, 2013
(86) PCT No.: PCT/US2013/062378

§ 371 Date: Feb. 18, 2016

(51) Int. Cl. G06F 7/58; H01L 43/08; H01L 43/10; G06F 1/16

(52) U.S. Cl. CPC G06F 7/588; G06F 1/1613; H01L 43/08; H01L 43/10

(57) ABSTRACT

Described is an apparatus for a voltage controlled nano-magnetic random number generator. The apparatus comprises: a free ferromagnetic layer; a fixed ferromagnetic layer positioned in a non-collinear direction relative to the free ferromagnet layer; and a first terminal coupled to the free ferromagnetic layer, the first terminal to provide a bias voltage to the free ferromagnetic layer. Described is also an integrated circuit comprising: a random number generator including a magnetic tunnel junction (MTJ) device with non-collinearly positioned free and fixed ferromagnetic layers; and a circuit to provide an adjustable bias voltage to the free ferromagnetic layer, the circuit to control variance of current generated by the random number generator.

### BACKGROUND

On chip micro-scale embedded random number generators (RNG) can enable wide range of secure features for consumer and enterprise applications. However, leading pseudo random number generators are software based or supplied from a networked source (e.g., National Institute of Standards and Technology (NIST)). Software based random number generators suffer from increased power and chip area to run the random number generator. Standardized algorithms for RNG are also prone to security threats. Software algorithms may produce an approximate random number sequence but with limited quality as measured by known tests for randomness.

Existing magnetic tunnel junction (MTJ) based random number generators suffer from several disadvantages. For example, known MTJ based RNGs are unable to generate Gaussian distributed noise, which is one of the most commonly used processes for communication encryption. Another disadvantage of known MTJ based RNGs is their inability to control the process of random number generation to allow variable mean and variance to be changed dynamically.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates an MTJ based RNG.

FIG. 1B illustrates a plot showing sensed random current from the MTJ, and normal noise distribution.

FIG. 2 illustrates a non-collinear MTJ device, according to one embodiment of the disclosure.

FIG. 3 illustrates a top view of the non-collinear MTJ device, according to one embodiment of the disclosure.

FIG. 4A illustrates a plot showing variance of magnet angle relative to magnetic barrier for the non-collinear MTJ device, according to one embodiment of the disclosure.

FIG. 4B illustrates variation of magnetic barrier relative to applied voltage for the non-collinear MTJ device, according to one embodiment of the disclosure.

FIG. 5A illustrates a plot showing noise current probability density for the non-collinear MTJ device, according to one embodiment of the disclosure.

FIG. 5B illustrates a plot showing cumulative probability vs. sensed current for the non-collinear MTJ device, according to one embodiment of the disclosure.

FIGS. 6A-B illustrate plots showing control of magnetic noise by varying magnetic barrier with applied voltage for the non-collinear MTJ device, according to one embodiment of the disclosure.

FIGS. 7A-B illustrate plots showing resetting condition of the non-collinear MTJ by applying high voltage to the non-collinear MTJ, according to one embodiment of the disclosure.

FIG. 8 illustrates a plot showing power spectral density of the current generated by the non-collinear MTJ, according to one embodiment of the disclosure.

FIG. 9 is a circuit for generating random analog/digital signal and for applying bias voltage to the non-collinear MTJ, according to one embodiment of the disclosure.

FIG. 10 is a flowchart of a method of forming the non-collinear MTJ device, according to one embodiment of the disclosure.

FIG. 11 is a smart device or a computer system or an SoC (system-on-chip) with a random number generator having the non-collinear MTJ, according to one embodiment of the disclosure.

### DETAILED DESCRIPTION

The embodiments describe a non-collinear (e.g., orthogonal) stacked in-plane Magnetic Tunnel Junction (MTJ) device with voltage dependent magnetic barriers as a controllable random number generator. In one embodiment, the random number generator provides a bell-shaped normal Gaussian distribution of noise compared to a non bell-shaped distribution of noise by traditional MTJ devices. In one embodiment, MTJ free and fixed ferromagnetic layers are positioned in a non-collinear position relative to one another to generate a normal distribution of MTJ sensed current. In one embodiment, a circuit is provided to generate a bias voltage to control magnetic barrier of the MTJ free ferromagnetic layer to enable control of variance of the generated MTJ current. In one embodiment, a circuit is provided to generate a bias voltage to lower the magnetic barrier of the MTJ to enable a clean reset of the random number generator.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical connection between the things that are connected, without any intermediary devices. The term “coupled” means either a direct electrical connection between the things that are connected or an indirect connection through one or more passive or active intermediary devices. The term “circuit” means one or more passive and/or active components that are arranged to cooperate with one another to provide a desired function. The term “signal” means at least one current signal, voltage signal or data/clock signal. The meaning of “a,” “an,” and “the” include plural references. The meaning of “in” includes “in ” and “on.”

The term “scaling” generally refers to converting a design (schematic and layout) from one process technology to another process technology. The term “scaling” generally also refers to downsizing layout and devices within the same technology node. The term “scaling” may also refer to adjusting (e.g., slow down) of a signal frequency relative to another parameter, for example, power supply level. The terms “substantially,” “close,” “approximately,” “near,” and “about,” generally refer to being within +/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors are metal oxide semiconductor (MOS) transistors, which include drain, source, gate, and bulk terminals. The transistors also include Tri-Gate and FinFet transistors, Gate All Around Cylindrical Transistors or other devices implementing transistor functionality like carbon nano tubes or spintronic devices. Source and drain terminals may be identical terminals and are interchangeably used herein. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

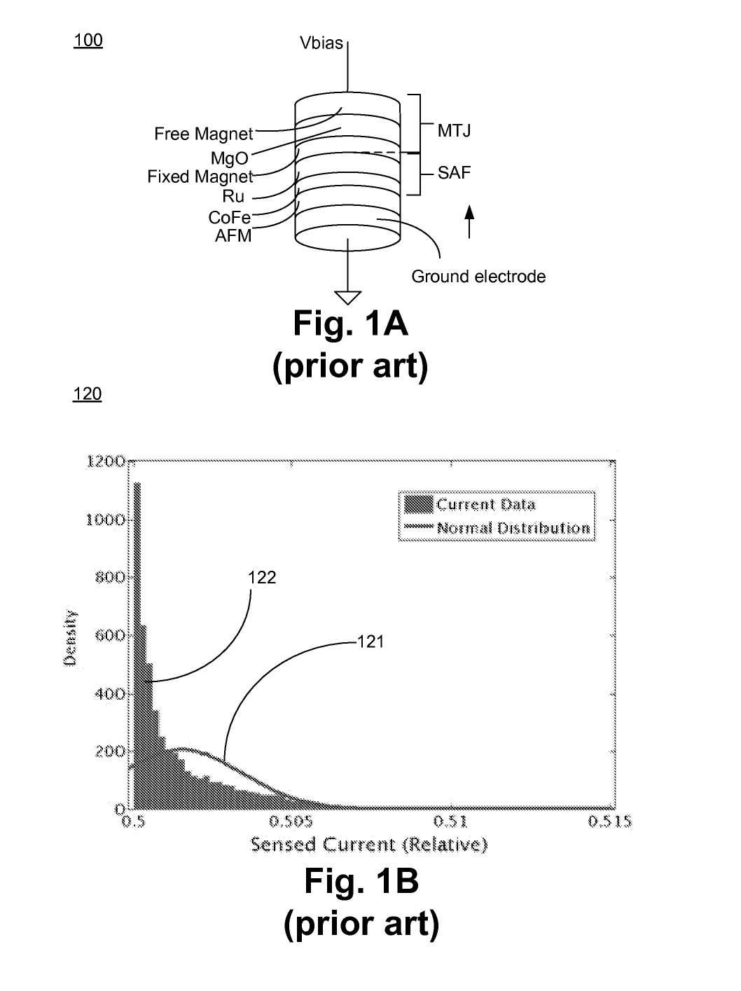

FIG. 1A illustrates an MTJ 100 based RNG. MTJ 100 is a traditional MTJ device with stacked layers all in the same linear plane. From the top, the first layer is a free ferromagnetic layer. The second layer from the top is an insulation layer formed from MgO. The fixed magnetic layer is typically formed by a ferromagnetic alloy e.g., CoFeB. The fixed layer, which starts from the third layer from the top, is composed of synthetic anti-ferromagnetic (SAF) stack (i.e., layers three and below from the top layer). The layers below the third layer from the top include layers formed from Ru, CoFe, AFM, and an electrode. The stack of CoFeB/Ru/CoFe form an anti-ferromagnetic exchange layer (AFM). The bottom synthetic SAF is held by a natural AFM and may be formed by PtMn or IrMn or similar alloys.

To operate MTJ 100 as a RNG, a voltage bias Vbias is applied to the free ferromagnetic layer, and a ground is coupled to the other end of MTJ 100. Upon application of Vbias, a current flows through MTJ 100, and can be sensed at the ground terminal. This current has random current properties allowing MTJ 100 to perform as a RNG. However, the distribution of the noise generated by the current through MTJ 100 is not a Gaussian distribution.

The dynamics of nanomagnets are strongly affected by the thermal noise. Thermal noise in nanomagnets manifest as fluctuations to the internal anisotropic field. The thermal noise can be considered as a result of the microscopic degrees of freedom of the conduction electrons and the lattice of the ferromagnetic element. At room temperature T, the thermal noise is described by a Gaussian white noise (with a time domain Dirac-delta auto-correlation). The noise field acts isotropically on the magnet. In presence of the noise, the Landau Lifshitz Gilbert (LLG) equation can be written as

$$\frac{\partial \hat{m}}{\partial t} = - γ {μ}_{0} [ \hat{m} \times {\overline{H}}_{eff} ( T ) ] + α [ \hat{m} \times \frac{\partial m}{\partial t} ] - \frac{{{I}^{′}}_{⊥}}{{eN}_{s}}$$

The internal field is described as:

H̅_{eff}(T)=H̅_{eff}+(Hᵢ\hat{x}+Hⱼŷ+Hₖ\hat{z})

The properties of the random thermo-magnetic noise are:

$$〈 {H}_{l} ( t ) 〉 = 0$$

$$〈 {H}_{l} ( t ) {H}_{k} ( {t}^{′} ) 〉 = \frac{2 α {k}_{B} T}{{μ}_{0}^{2} γ {M}_{s} V} δ ( t - {t}^{′} ) {δ}_{lk}$$

The initial conditions of the magnets are randomized to be consistent with the distribution of initial angles of magnet moments in a large collection of magnets. At temperature T, the initial angle of the magnets follows:

$$〈 {θ}^{2} 〉 = \frac{kT}{{M}_{s} V {μ}_{0} {H}_{ani}}$$

‘k’ is Boltzmann constant, ‘T’ is temperature, Mₛ is saturation magnetization, ‘V’ is volume, μₒ is magnetic permeability, and Hₐₙᵢ anisotropic field.

FIG. 1B illustrates a plot 120 showing sensed random current from MTJ 100, and normal noise distribution. The x-axis is current sensed in mA, and the y-axis is current density. Waveform 121 is the normal distribution of the sensed current while waveform 122 is the current density as voltage Vbias is varied. As shown in plot 120, MTJ 100 does not exhibit a bell-shaped Gaussian distribution. Furthermore, MTJ 100 is unable to dynamically control the process of random number generation to allow variable mean and variance to be changed dynamically.

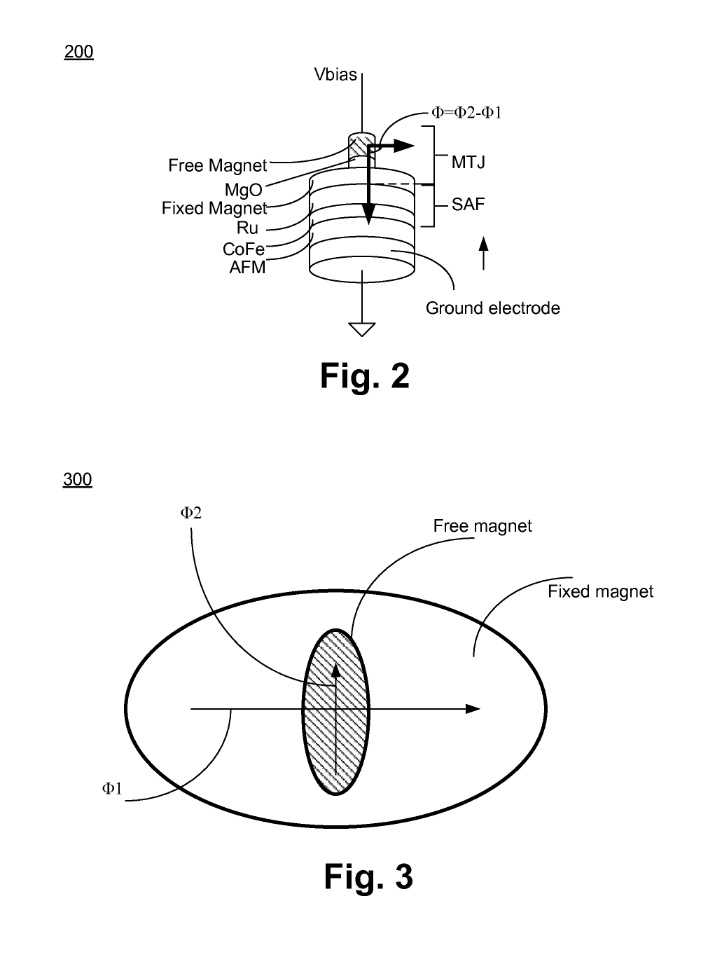

FIG. 2 illustrates a non-collinear MTJ device 200, according to one embodiment of the disclosure. It is pointed out that those elements of FIG. 2 having the same reference numbers (or names) as the elements of any other figure can operate or function in any manner similar to that described, but are not limited to such.

In one embodiment, non-collinear MTJ device 200 comprises stacked free and fixed ferromagnetic layers which are non-collinear with respect to each other. The term “non-collinear” generally refers to two layers having different magnetic angles. For example, if one layer is orthogonal to another layer with respect to their magnetic angles, then the two layers are non-collinear layers. In one embodiment, the non-collinear stacked free and fixed ferromagnetic layers of MTJ 200 generate a normal Gaussian distribution of current sensed by MTJ 200. In one embodiment, free ferromagnetic layer is smaller in size than the fixed ferromagnetic layer size. In one embodiment, a terminal is coupled to the free ferromagnetic layer which forms one end of the MTJ device. In such an embodiment, the other end of the MTJ device forms the second terminal coupled to the fixed ferromagnetic layer. In one embodiment, the second terminal is ground.

While the embodiments of MTJ 200 illustrate oval or circular stacked layers, the stacked layers can be rectangular or other shapes so long as the free ferromagnetic layer is non-collinear with respect to the fixed ferromagnetic layer. In one embodiment, the anisotropy of the nanomagnets is controlled by the shape of the free and fixed ferromagnetic layers.

In one embodiment, a circuit is provided which generates Vbias for the free ferromagnetic layer. In one embodiment, the circuit is operable to adjust the level of Vbias to control the magnetic barrier of the magnets of MTJ 200. In such an embodiment, current generated by MTJ 200 due to the application of Vbias allows for controlling variance of the generated current. In one embodiment, the circuit is operable to reset the free ferromagnetic layer by adjusting Vbias which in turn lowers the magnetic barrier. In one embodiment, another circuit is provided to sense current through the Vbias terminal (also referred here as the first terminal) coupled to free ferromagnetic layer of MTJ 200. In one embodiment, a circuit is provided to convert the sensed current into a digital representation to provide a seed for a random number generator.

FIG. 3 illustrates a top view 300 of the non-collinear MTJ device 200, according to one embodiment of the disclosure. It is pointed out that those elements of FIG. 3 having the same reference numbers (or names) as the elements of any other figure can operate or function in any manner similar to that described, but are not limited to such.

In this embodiment, top view 300 shows two oval/circular shaped objects which represent the free ferromagnetic layer and the fixed ferromagnetic layer of MTJ 200. In this embodiment, both free ferromagnetic layer and the fixed ferromagnetic layer are orthogonal to one another i.e., the difference between the magnetic angle Φ1 of the fixed ferromagnetic layer relative to the magnetic angle Φ2 of the free ferromagnetic layer is 90 degrees. In such an embodiment, normal Gaussian noise distribution is observed in the MTJ 200 sensed current.

In one embodiment, voltage control of an MTJ is enabled by the lowering/tuning of the barrier in an in-plane MTJ in parallel configuration. The barrier is tuned with voltage as:

E_{b}^{±}(V)=E_{b}⁰(1±(C₁V+C₂V²))^{3/2}

where, E_{b} is the barrier energy, E_{b}⁰ is barrier at zero voltage, C₁ is linear voltage co-efficient, C₂ is quadratic voltage coefficient, and V is the applied Vbias.

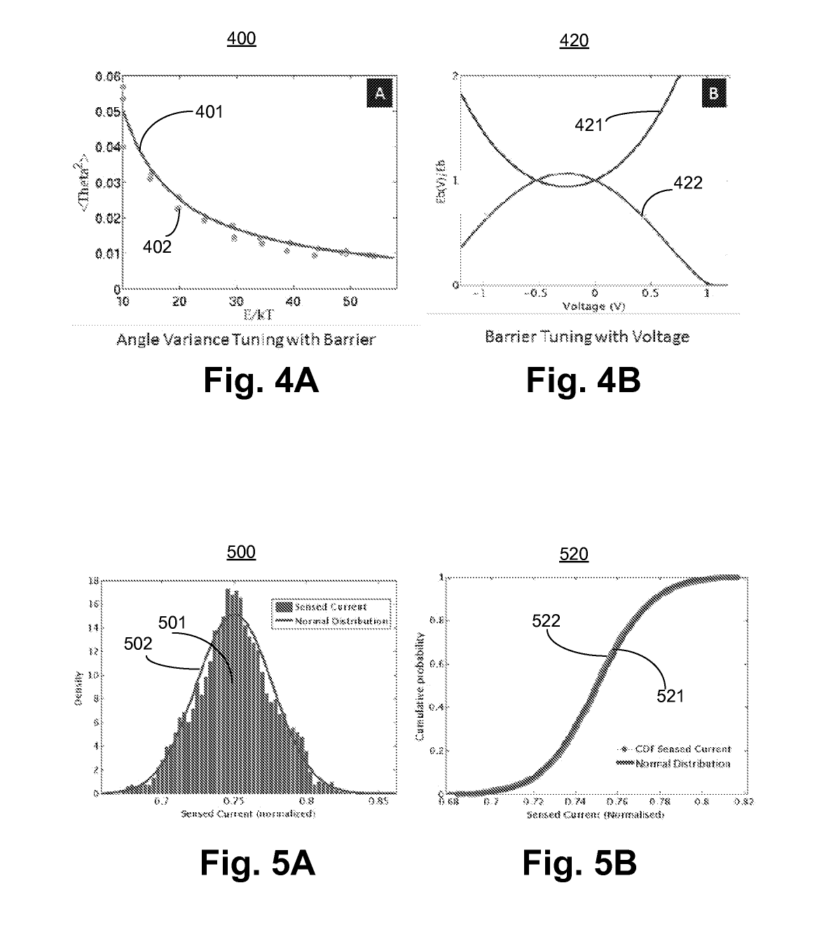

FIG. 4A illustrates a plot 400 showing variance of magnetic angle relative to magnetic barrier for the non-collinear MTJ device, according to one embodiment. It is pointed out that those elements of FIG. 4A having the same reference numbers (or names) as the elements of any other figure can operate or function in any manner similar to that described, but are not limited to such.

The x-axis is strength of magnet expressed as E/kT, where ‘E’ is the barrier energy of the MTJ magnets, ‘k’ is Boltzmann constant, and ‘T’ is temperature. The y-axis is square of the difference in angles i.e., (Φ2−Φ1)² which indicates angle variation with respect to magnetic barrier strength. Here, 0.01 for the square of the magnetic angles indicates low angle variation while 0.06 indicates high angle variation. Here, 10 for E/kT indicates a weak barrier while 50 for E/kT indicates a stronger barrier. Plot 400 illustrates samples 402 and smooth curve 401 representing the samples. Plot 400 illustrates the effect of thermal noise on the magnet. The variation in angle is shown as a function of the barrier.

FIG. 4B illustrates a plot 420 showing variation of magnetic barrier relative to applied voltage for the non-collinear MTJ device, according to one embodiment. It is pointed out that those elements of FIG. 4B having the same reference numbers (or names) as the elements of any other figure can operate or function in any manner similar to that described, but are not limited to such.

Here, x-axis is bias voltage in Volts. Here, y-axis is E_{b}(V)/E_{b} which indicates the strength of the barrier. Plot 420 shows two waveforms. Waveform 421 shows the case of an MTJ device with anti-parallel free and fixed ferromagnetic layers, and corresponding relation between applied Vbias on first terminal and varying strength of barrier of the magnet. Waveform 422 shows the case of an MTJ device with parallel free and fixed ferromagnetic layers, and corresponding relation between applied Vbias on first terminal and varying strength of barrier of the magnet. In both cases (of waveforms 421 and 422 ), the free and fixed ferromagnetic layers are non-collinear. Waveforms 421 and 422 illustrate that for MTJ 200, magnetic barrier is tunable with Vbias.

FIG. 5A illustrates a plot 500 showing noise current probability density for the non-collinear MTJ device, according to one embodiment. It is pointed out that those elements of FIG. 5A having the same reference numbers (or names) as the elements of any other figure can operate or function in any manner similar to that described, but are not limited to such.

Here, x-axis is normalized sensed current, while the y-axis is current probability density through MTJ 200. Plot 500 illustrates waveform 501 which are vertical bars showing normalized sensed current. Plot 500 also illustrates waveform 502 which is the normal Gaussian generated current probability density for MTJ 200. Compared to MTJ 100, which exhibits a non Gaussian current probability, MTJ 200 generates a normal Gaussian generated current probability density which allows MTJ 200 to operate as a better random number generator than MTJ 100.

FIG. 5B illustrates a plot 520 showing cumulative probability vs. sensed current for the non-collinear MTJ device, according to one embodiment. It is pointed out that those elements of FIG. 5B having the same reference numbers (or names) as the elements of any other figure can operate or function in any manner similar to that described, but are not limited to such.

Here, x-axis is normalized sensed current and y-axis is cumulative probability of the noise currents generated by MTJ 200. Plot 520 illustrates two waveforms abutting each other—waveforms 521 and 522. Plot 520 reaffirms the generation of normal Gaussian current probability using MTJ 200. The generated noise using MTJ 200 is described by a white noise process with a delta function autocorrelation or a contact power spectral density characteristic to a white noise process. Plot 520 shows that the cumulative distribution function (CDF) of the current follows a Gaussian CDF.

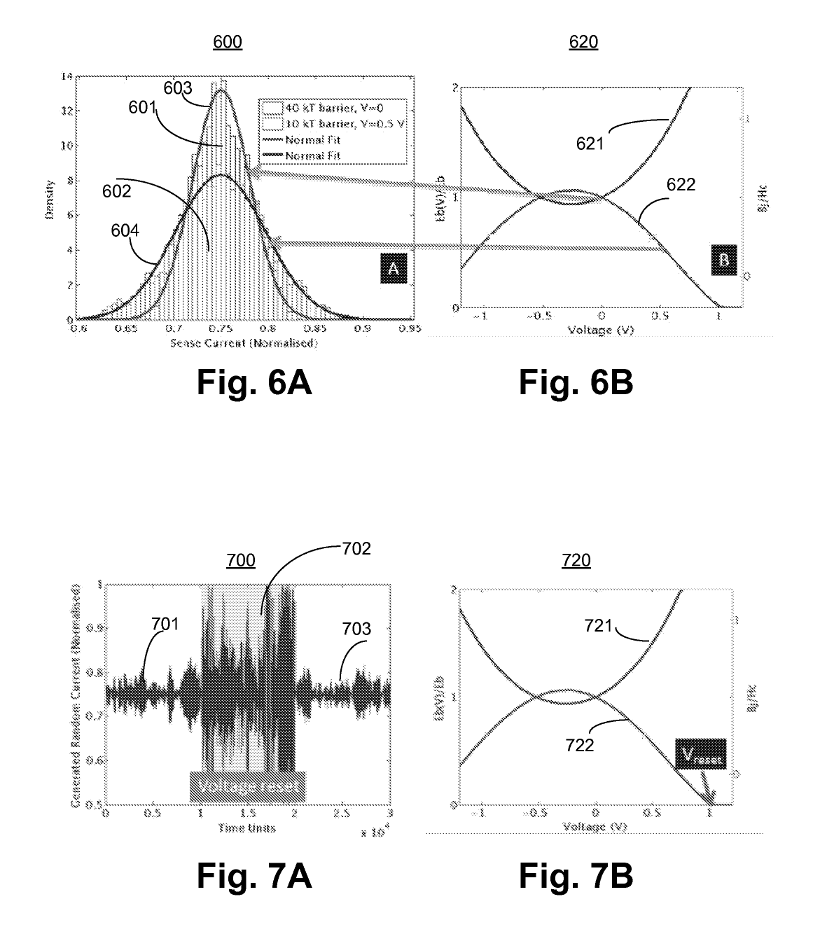

FIGS. 6A-B illustrate plots 600 and 620 respectively showing control of magnetic noise by varying magnetic barrier with applied voltage for the non-collinear MTJ device, according to one embodiment. It is pointed out that those elements of FIGS. 6A-B having the same reference numbers (or names) as the elements of any other figure can operate or function in any manner similar to that described, but are not limited to such. FIG. 6A illustrates variance of the magnetic angle with voltage control due to barrier tuning of MTJ 200. FIG. 6B illustrates variation of the magnetic barrier with applied voltage for MTJ 200.

For plot 600, x-axis is normalized current sensed through MTJ 200 while the y-axis is probability density of sensed current. Plot 600 shows sense current bars 601 for the case when applied Vbias voltage is zero and the magnetic barrier energy is 40 kT. Sense current bars 602 (shorter bars compared to bars 601 ) are for the case when applied Vbias is 0.5 V and magnetic barrier energy is 10 kT. In these embodiments, for MTJ 200, by adjusting Vbias by the circuit generating it, the size/shape of current density probability is adjusted because adjusting Vbias adjusts the magnetic barrier strength. In one embodiment, as voltage of Vbias is raised, the magnetic barrier strength of MTJ 200 weakens.

Waveform 603 is a normal Gaussian distribution of current noise for anti-parallel magnets of MTJ 200 as shown by waveform 621 of FIG. 6B. Waveform 604 is a normal Gaussian distribution of current noise for parallel magnets of MTJ 200 as shown by waveform 622 of FIG. 6B. Plot 620 illustrates that the magnet thermal barrier can be tuned as a function of voltage for in-plane magnets. The change in shape of waveforms 621 and 622 is caused by different magnet orientation in MTJ 200 (i.e., 621 shows the cause when the magnets are anti-parallel and 622 shows the case when the magnets are parallel). In the embodiments, an applied voltage Vbias allows for control of the magnet thermal barrier which in turn allows a control of the angle variance of the magnet.

FIGS. 7A-B illustrate plots 700 and 720 respectively showing resetting condition of the non-collinear MTJ device by applying high voltage to the non-collinear MTJ, according to one embodiment. It is pointed out that those elements of FIGS. 7A-B having the same reference numbers (or names) as the elements of any other figure can operate or function in any manner similar to that described, but are not limited to such.

Plot 700 of FIG. 7A shows fluctuation in random current generated in MTJ 200 by variation in voltage level of Vbias. Here, the x-axis is time and the y-axis is normalized random current generated in MTJ 200. Plot 700 is divided into three sections—701, 702, and 703. Section 701 is the fluctuation in normalized random current for low Vbias voltage. Section 702 is the fluctuation in normalized random current when Vbias is set to 1 V. This section shows that the noise process of MTJ 200 can be reset to provide a new operating condition (i.e., random seed) for generating noise variable. The term “reset” here refers to generation of uncorrelated magnetic dynamics. Section 703 is the fluctuation in normalized random current when Vbias is lowered than 1 V. Plot 720 in FIG. 7B illustrates the application of reset voltage to randomize the location of the random variable while FIG. 7A shows the resultant fluctuation. Here, 721 shows the barrier for anti-parallel configuration as a function of voltage, while 722 shows the barrier for parallel configuration as a function of voltage.

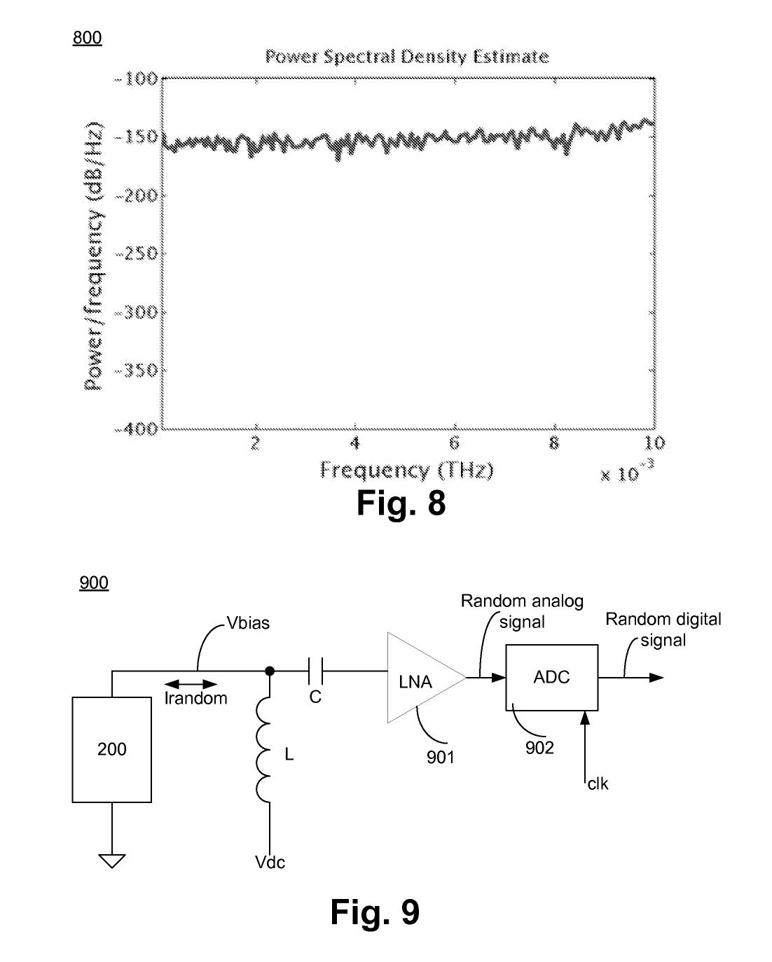

FIG. 8 illustrates a plot 800 showing power spectral density of the current generated by the non-collinear MTJ 200 device, according to one embodiment. It is pointed out that those elements of FIG. 8 having the same reference numbers (or names) as the elements of any other figure can operate or function in any manner similar to that described, but are not limited to such.

Here, x-axis is frequency (TIIz) and y-axis is power/frequency (dB/Hz). The waveform in plot 800 shows white noise from the sensed and/or generated noise current from MTJ 200 by application of Vbias. Plot 800 shows that the current generated by MTJ 200 has little to no correlation over a wise frequency range. This means that MTJ 200 device can be used as random noise generator over a large frequency range. In one embodiment, angle between MTJ nanomagnets can be controlled via fabrication/anneal conditions to enable another control variable for generating the noise.

FIG. 9 is a circuit 900 for generating random analog/digital signal and for applying bias voltage to the non-collinear MTJ device, according to one embodiment. It is pointed out that those elements of FIG. 9 having the same reference numbers (or names) as the elements of any other figure can operate or function in any manner similar to that described, but are not limited to such.

In one embodiment, circuit 900 comprises low noise amplifier (LNA) 901, analog-to-digital converter (ADC), inductor L, and capacitor C. In one embodiment, a DC (direct current) voltage Vdc is applied to one end of the inductor L. In one embodiment, the other end of the inductor is coupled to a terminal of the capacitor C. In one embodiment, the other terminal of capacitor C is coupled to an input of LNA 901. In one embodiment, output of LNA 901 is a random analog signal which is received at the input of ADC 902. In one embodiment, LNA has a NF (noise factor) below 1 dB. In one embodiment, gain of LNA 901 is in the range of 20-30 dB. In other embodiments, other values for gain for LNA 901 may be used. In one embodiment, output of ADC 902 is a random digital signal which is further used by a logic unit to generate a random number. In one embodiment, ADC 902 operates using clock clk having frequency fclk.

In one embodiment, the other end of the inductor ‘L’ and one end of capacitor ‘C’ is coupled to the first terminal of MTJ 200. In this embodiment, Vdc provides the DC level for Vbias while the inductor provides the Vbias. As Vbias varies, current through MTJ 200 device varies generating Irandom current. In one embodiment, Irandom current provides a normal Gaussian current noise distribution. In one embodiment, to reset MTJ 200 device, Vdc is raised to a high level. In one embodiment, the second terminal of the MTJ 200 device s coupled to ground. In one embodiment, the ground is an RF (radio-frequency) ground. In one embodiment, an analog random number generator is realized by using the output of LNA 901. In one embodiment, a digital random number generator is realized by using the output of ADC 902.

In this embodiment, both the Vbias application and the corresponding sensing of MTJ current is achieved by circuit 900. In other embodiments, current sensing is performed at the ground terminal of MTJ 200 device and adjustable Vbias is applied to the first terminal of MTJ 200 device.

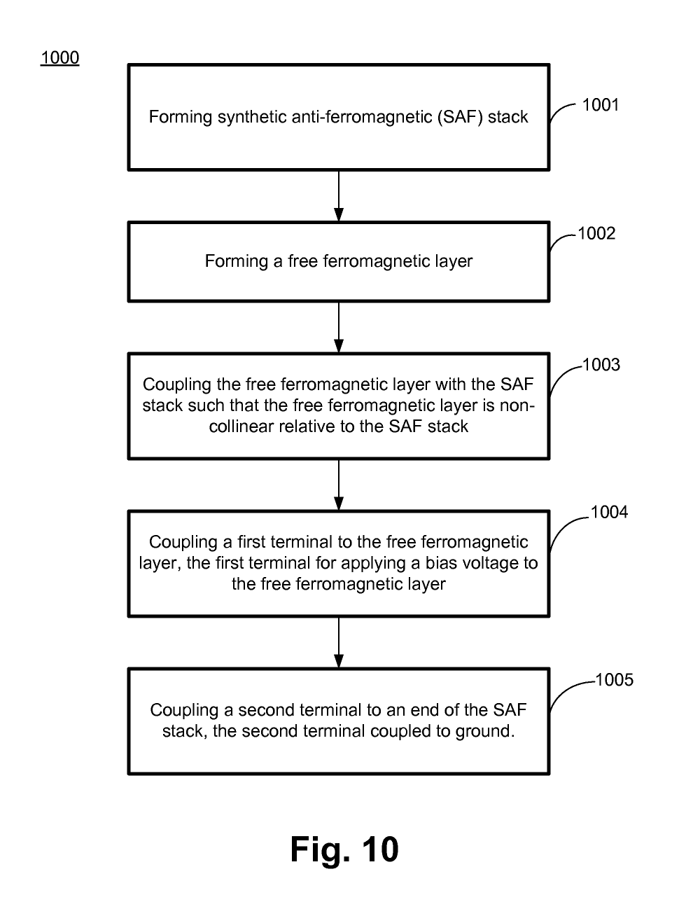

FIG. 10 is a flowchart 1000 of a method of forming the non-collinear MTJ 200 device, according to one embodiment of the disclosure. Although the blocks in the flowcharts with reference to FIG. 10 are shown in a particular order, the order of the actions can be modified. Thus, the illustrated embodiments can be performed in a different order, and some actions/blocks may be performed in parallel. Some of the blocks and/or operations listed in FIG. 10 are optional in accordance with certain embodiments. The numbering of the blocks presented is for the sake of clarity and is not intended to prescribe an order of operations in which the various blocks must occur. Additionally, operations from the various flows may be utilized in a variety of combinations. It is pointed out that those elements of FIG. 10 having the same reference numbers (or names) as the elements of any other figure can operate or function in any manner similar to that described, but are not limited to such.

At block 1001, SAF stack is formed i.e., fixed ferromagnetic layer is formed. At block 1002, free ferromagnetic layer is formed. At block 1003, SAF stack is coupled to the free ferromagnetic layer such that the free ferromagnetic layer and the SAF stack are separated by

MgO (or any other insulation material). The SAF stack is coupled to the free ferromagnetic stack such that the SAF stack is non-collinear relative to the free ferromagnetic stack. At block 1004, a first terminal is coupled to the free ferromagnetic layer. The first terminal is used to provide bias voltage. At block 1005, a second terminal is coupled to the SAF stack. The second terminal is coupled to ground.

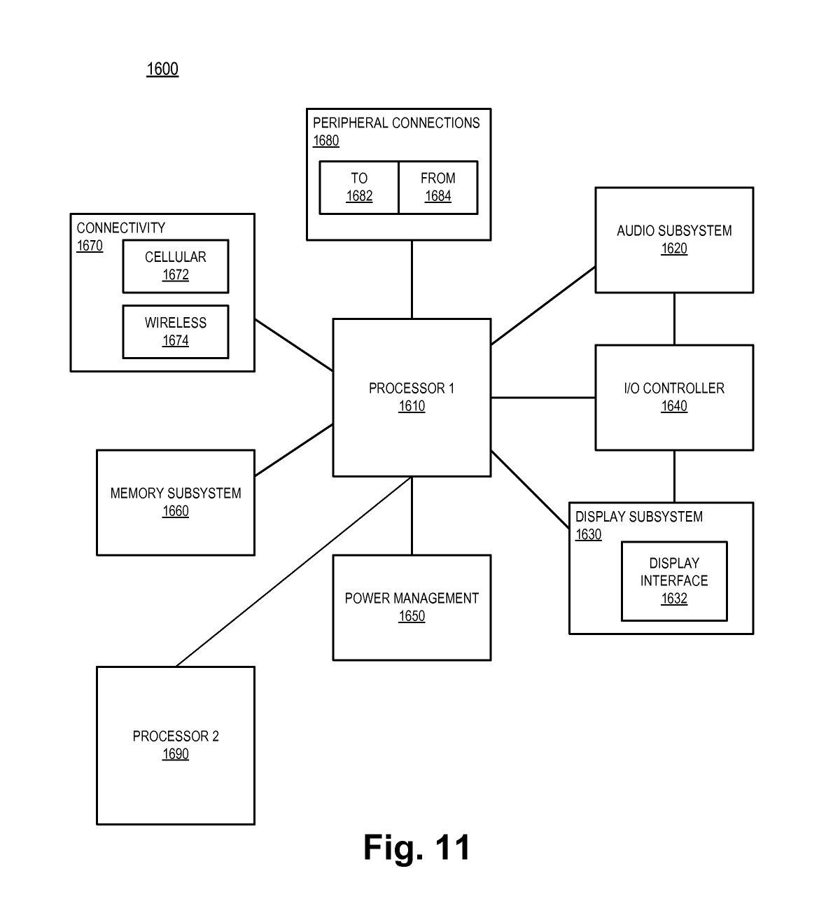

FIG. 11 is a smart device or a computer system 1600 or an SoC (system-on-chip) with a random number generator having the non-collinear MTJ, according to one embodiment of the disclosure. It is pointed out that those elements of FIG. 11 having the same reference numbers (or names) as the elements of any other figure can operate or function in any manner similar to that described, but are not limited to such.

FIG. 11 illustrates a block diagram of an embodiment of a mobile device in which flat surface interface connectors could be used. In one embodiment, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In one embodiment, computing device 1600 includes a first processor 1610 with random number generator having the non-collinear MTJ (e.g., MTJ 200 ) device, according to the embodiments discussed. Other blocks of the computing device 1600 may also include the random number generator having the non-collinear MTJ device of the embodiments. The various embodiments of the present disclosure may also comprise a network interface within 1670 such as a wireless interface so that a system embodiment may be incorporated into a wireless device, for example, cell phone or personal digital assistant.

In one embodiment, processor 1610 (and/or processor 1690 ) can include one or more physical devices, such as microprocessors, application processors, microcontrollers, programmable logic devices, or other processing means. In one embodiment, processor 1690 is optional. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In one embodiment, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In one embodiment, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In one embodiment, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660 ) for storing the computer-executable instructions (e.g., instructions to implement any other processes discussed herein). The machine-readable medium (e.g., memory 1660 ) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1680 include hardware interfaces and connectors, as well as software components (e.g., drivers, protocol stacks) to make peripheral connections. It will be understood that the computing device 1600 could both be a peripheral device (“to” 1682 ) to other computing devices, as well as have peripheral devices (“from” 1684 ) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, in one embodiment an apparatus comprises: a free ferromagnetic layer; a fixed ferromagnetic layer positioned in a non-collinear direction relative to the free ferromagnetic layer; and a first terminal coupled to the free ferromagnetic layer, the first terminal to provide a bias voltage to the free ferromagnetic layer. In one embodiment, apparatus further comprises a second terminal coupled to the fixed ferromagnetic layer. In one embodiment, the second terminal is coupled to ground.

In one embodiment, the apparatus further comprises a circuit to generate the bias voltage with an adjustable voltage level. In one embodiment the circuit is operable to reset the free ferromagnetic layer by adjusting the bias voltage. In one embodiment, the circuit is operable to randomize current through the first terminal by adjusting the bias voltage. In one embodiment, the free ferromagnetic layer and the fixed ferromagnetic layer form a stacked in-plane magnetic tunnel junction (MTJ) device.

In one embodiment, the apparatus further comprises a current sensor to sense current through the first terminal, the current being generated due to the bias voltage. In one embodiment, the free ferromagnetic layer is positioned 90 degrees relative to the fixed ferromagnetic layer.

In another example, in one embodiment a system is provided which comprises: a memory; a processor coupled to the memory, the processor having the above apparatus; and a wireless interface for allowing the processor to communicate with another device.

In another example, an integrated circuit having a random number generator is provided, which comprises: a magnetic tunnel junction (MTJ) device with non-collinearly positioned free and fixed ferromagnetic layers; and a circuit to provide an adjustable bias voltage to the free ferromagnetic layer, the circuit to control variance of current sensed by the MTJ device. In one embodiment, the integrated circuit further comprises a first terminal coupled to the free ferromagnetic layer to receive the adjustable bias voltage.

In one embodiment, the integrated circuit further comprises a current sensor to sense current through the first terminal, the current being generated due to the bias voltage. In one embodiment, the circuit is operable to reset the free ferromagnetic layer by adjusting the bias voltage. In one embodiment, the circuit is operable to randomize current through the first terminal by adjusting the bias voltage. In one embodiment, the free ferromagnetic layer is positioned 90 degrees relative to the fixed ferromagnetic layer.

In another example, in one embodiment a system is provided which comprises a memory; an integrated circuit coupled to the memory, the integrated circuit having a random number generator according the integrated circuit discussed above; and a wireless interface for allowing the processor to communicate with another device.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
a free ferromagnetic layer;
a fixed ferromagnetic layer positioned in a non-collinear direction relative to the free ferromagnetic layer; and
a first terminal coupled to the free ferromagnetic layer, the first terminal to provide a bias voltage to the free ferromagnetic layer.

2. The apparatus of claim 1 further comprises a second terminal coupled to the fixed ferromagnetic layer.

3. The apparatus of claim 2, wherein the second terminal is coupled to ground.

4. The apparatus of claim 1 further comprising a circuit to generate the bias voltage with an adjustable voltage level.

5. The apparatus of claim 4, wherein the circuit is operable to reset the free ferromagnetic layer by adjusting the bias voltage.

6. The apparatus of claim 4, wherein the circuit is operable to randomize current through the first terminal by adjusting the bias voltage.

7. The apparatus of claim 1, wherein the free ferromagnetic layer and the fixed ferromagnetic layer form a stacked in-plane magnetic tunnel junction (MTJ) device.

8. The apparatus of claim 1 further comprises a current sensor to sense current through the first terminal, the current being generated due to the bias voltage.

9. The apparatus of claim 1, wherein the free ferromagnetic layer is positioned 90 degrees relative to the fixed ferromagnetic layer.

10. An integrated circuit having a random number generator, the integrated circuit comprising:
a magnetic tunnel junction (MTJ) device with non-collinearly positioned free and fixed ferromagnetic layers; and
a circuit to provide an adjustable bias voltage to the free ferromagnetic layer, the circuit to control variance of current sensed by the MTJ device.

11. The integrated circuit of claim 10 further comprises a first terminal coupled to the free ferromagnetic layer to receive the adjustable bias voltage.

12. The integrated circuit of claim 11 further comprises a current sensor to sense current through the first terminal, the current being generated due to the bias voltage.

13. The integrated circuit of claim 10, wherein the circuit is operable to reset the free ferromagnetic layer by adjusting the bias voltage.

14. The integrated circuit of claim 10, wherein the circuit is operable to randomize current through the first terminal by adjusting the bias voltage.

15. The integrated circuit of claim 10, wherein the free ferromagnetic layer is positioned 90 degrees relative to the fixed ferromagnetic layer.

16. A system comprising:
a memory;
a processor coupled to the memory, the processor having an apparatus which comprises:
a free ferromagnetic layer;
a fixed ferromagnetic layer positioned in a non-collinear direction relative to the free ferromagnetic layer; and
a first terminal coupled to the free ferromagnetic layer, the first terminal to provide a bias voltage to the free ferromagnetic layer; and
a wireless interface for allowing the processor to communicate with another device.

17. The system of claim 16 further comprises a display unit.

18. The system of claim 17, wherein the display unit is a touch screen.

19. A system comprising:
a memory;
a processor coupled to the memory, the processor having a random number generator, the processor comprises:
a wireless interface for allowing the processor to communicate with another device.
